(19) United States
(12) Patent Application Publication
(10) Pub. No.: US 2025/0221211 A1
(43) Pub. Date: Jul. 3, 2025

(54) DISPLAY PANEL AND DISPLAY DEVICE

(71) Applicants: Hefei Visionox Technology Co., Ltd., Hefei (CN); KunShan Go-Visionox Opto-Electronics Co., Ltd, Kunshan (CN)

(72) Inventors: Zhiwei ZHOU, Hefei (CN); Jinfang ZHANG, Hefei (CN); Lu ZHANG, Hefei (CN); Meng ZHANG, Hefei (CN)

(73) Assignees: Hefei Visionox Technology Co., Ltd., Hefei (CN); KunShan Go-Visionox Opto-Electronics Co., Ltd, Kunshan (CN)

(21) Appl. No.: 18/987,493

(22) Filed: Dec. 19, 2024

(30) Foreign Application Priority Data
Jan. 2, 2024 (CN) 202410008807.3

(51) Int. Cl. H10K 59/131; H10K 59/122

(52) U.S. Cl. CPC H10K 59/131; H10K 59/122

(57) ABSTRACT

A display panel and a display device, in which the display panel includes an array base plate with a substrate, a first conductive layer, an insulating layer and a second conductive layer, the first conductive layer includes a first signal line and a second signal line each extending in a first direction, the second conductive layer includes a third signal line and a fourth signal line each extending in a second direction and transmitting the same signal; in a direction perpendicular to the substrate, the first signal line and the third signal line have a first overlapping area and are electrically connected in the first overlapping area, the second signal line and the fourth signal line have a fourth overlapping area and are electrically connected in the fourth overlapping area.

### CROSS-REFERENCE TO RELATED APPLICATIONS

This application claims priority to Chinese Patent Application No. 202410008807.3, titled “DISPLAY PANEL AND DISPLAY DEVICE” and filed on Jan. 2, 2024, which is hereby incorporated by reference in its entirety.

### TECHNICAL FIELD

The present application belongs to the field of display technology, and in particular, relates to a display panel and a display device.

### BACKGROUND

Organic Light Emitting Diode (OLED) and flat panel display devices based on technologies such as Light Emitting Diode (LED) are widely used in various consumer electronic products such as mobile phones, televisions, laptops, desktop computers, etc. due to their advantages such as high image quality, power saving, thin body and wide application range, becoming a mainstream of display devices.

However, the performance of current OLED display products needs to be improved.

### SUMMARY

The embodiments of the present application provide a display panel and a display device, which can improve the color shift of the display panel and enhance the performance of the display panel.

The embodiments of the first aspect of the embodiments of the present application provide a display panel, including:
an array base plate comprising a substrate and a first conductive layer, an insulating layer, and a second conductive layer stacked in sequence on a side of the substrate; where the first conductive layer comprises a first signal line and a second signal line each extending along a first direction, the second conductive layer comprises a third signal line and a fourth signal line each extending along a second direction, the first direction intersects with the second direction, and the first signal lines and the second signal lines are arranged along the second direction, the third signal lines and the fourth signal lines are arranged along the first direction and transmit the same signal; and
in a direction perpendicular to the substrate, each of the first signal lines and each of the third signal lines have a first overlapping area, each of the first signal lines and each of the fourth signal lines have a second overlapping area, each of the second signal lines and each of the third signal lines have a third overlapping area, and each of the second signal lines and each of the fourth signal lines have a fourth overlapping area; the first signal line and the third signal line are electrically connected in the first overlapping area, the first signal line and the fourth signal line are insulated in the second overlapping area and/or the second signal line and the third signal line are insulated in the third overlapping area, the second signal line and the fourth signal line are electrically connected in the fourth overlapping area, orthographic projections of the first overlapping area and the fourth overlapping area on the substrate are located outside orthographic projections of pixel openings on the substrate, and orthographic projections of the second overlapping area and the third overlapping area on the substrate are at least partially located within orthographic projections of pixel openings on the substrate, where the pixel openings are located on a side of the array base plate in a direction from the substrate to the insulating layer.

The embodiments of the second aspect of the present application also provide a display panel, comprising an array base plate including a substrate and a first semiconductor layer, a first metal layer, a second metal layer, a second semiconductor layer, a third metal layer, a fourth metal layer and a fifth metal layer stacked in a direction away from the substrate, where
the array base plate comprises a first type transistor, a second type transistor and a capacitor, the first semiconductor layer is configured to form a source region, a drain region and a channel region of the first type transistor, the first metal layer is configured to form a gate of the first type transistor and a first polar plate of the capacitor, the second metal layer is configured to form a bottom gate of the second type transistor, the second semiconductor layer is configured to form a source region, a drain region and a channel region of the second type transistor, the third metal layer is configured to form a top gate of the second type transistor, and the fourth metal layer is configured to form sources and drains of the first type transistor and the second type transistor;
where one of the first metal layer, the second metal layer, the third metal layer and the fourth metal layer is formed with a first signal line and a second signal line each extending along a first direction and arranged in the second direction, and the fourth metal layer is formed with a third signal line and a fourth signal line each extending along the second direction and arranged in the first direction, the first direction intersects with the second direction, and the third signal lines and the fourth signal lines transmit a same signal; and
in a direction perpendicular to the substrate, each of the first signal lines and each of the third signal lines have a first overlapping area, each of the first signal lines and each of the fourth signal lines have a second overlapping area, each of the second signal lines and each of the third signal lines have a third overlapping area, and each of the second signal lines and each of the fourth signal line have a fourth overlapping area; the first signal line and the third signal line are electrically connected in the first overlapping area, the first signal line and the fourth signal line are insulated in the second overlapping area and/or the second signal line and the third signal line are insulated in the third overlapping area, the second signal line and the fourth signal line are electrically connected in the fourth overlapping area, orthographic projections of the first overlapping area and the fourth overlapping area on the substrate are located outside orthographic projections of pixel openings on the substrate, and orthographic projections of the second overlapping area and the third overlapping area on the substrate are at least partially located within orthographic projections of pixel openings on the substrate.

An embodiment of the second aspect of the present application further provides a display device, comprising any display panel provided by the first aspect of the present application.

In the above-mentioned display panel provided in the present application, signals in the first signal lines and the third signal lines are the same, and the first signal lines and the third signal lines have and are electrically connected at first overlapping areas formed at intersections thereof, so that the first signal lines and the third signal lines form a network structure. An orthographic projection of a first overlapping area on the substrate does not overlap an orthographic projection of a pixel opening on the substrate, so that the first signal lines and the third signal lines may be electrically connected through vias at first overlapping areas; the vias are not located in the areas of the pixel openings, so that the presence of the vias may not cause the light-emitting units corresponding to the pixel openings to display poorly caused by the unevenness of an upper film layer due to the vias. The signals in the second signal lines and the fourth signal lines are the same, and the second signal lines and the fourth signal lines have and are electrically connected at fourth overlapping areas formed at intersections thereof, so that the second signal lines and the fourth signal lines form a network structure. An orthographic projection of a fourth overlapping area on the substrate does not overlap an orthographic projection of a pixel opening on the substrate, that is, the second signal lines and the fourth signal lines may be electrically connected through vias at fourth overlapping areas, and the vias are not located in the areas of the pixel openings, so that the presence of the vias may not cause the light-emitting units corresponding to the pixel openings to display poorly caused by the unevenness of an upper film layer due to the vias. Each of the first signal lines and each of the fourth signal lines have a second overlapping area, each of the second signal lines and each of the third signal lines have a third overlapping area, the first signal line and the fourth signal line are insulated in the second overlapping area, the second signal line and the third signal line are insulated in the third overlapping area, and the orthographic projections of the second overlapping area and the third overlapping area on the substrate are at least partially located within orthographic projections of pixel openings on the substrate, so that there is no need to arrange vias at positions of the second overlapping area and the third overlapping area, and the display yield of the light-emitting unit corresponding to the pixel opening may not be affected. The above-mentioned display panel provided in the present application realizes that the first signal line and the third signal line are electrically connected, and the second signal line and the fourth signal line are electrically connected, so that the orthographic projections of the vias required for electrical connection on the substrate are all located outside the orthographic projection of the pixel opening on the substrate, thereby improving the problem of large color shift caused by the presence of the vias affecting the electrode flatness of the light-emitting unit in the pixel opening, and improving the display quality of the display panel.

### BRIEF DESCRIPTION OF THE DRAWINGS

In order to more clearly illustrate the technical solutions of the embodiments of the present application, the drawings required for use will be introduced briefly in the embodiments of the present application below, apparently, the drawings described below are only some embodiments of the present application. Those skilled in the art may also obtain other drawings based on these drawings without creative work.

FIG. 1 is a schematic structural diagram of a display panel provided in an embodiment of the present application;

FIG. 2 is a cross-sectional view along P-P′ in FIG. 1;

FIG. 3 is a partial enlarged view of the region Q in FIG. 1;

FIG. 4 is a partial enlarged view of the region Q in FIG. 1;

FIG. 5 is a partial enlarged view of the region Q in FIG. 1;

FIG. 6 is a partial enlarged view of the region Q in FIG. 1;

FIG. 7 is a partial enlarged view of the region Q in FIG. 1;

FIG. 8 is a partial enlarged view of the region Q in FIG. 1;

FIG. 9 is a partial enlarged view of the region Q in FIG. 1;

FIG. 10 is a partial enlarged view of the region Q in FIG. 1;

FIG. 11 is a partial enlarged view of the region Q in FIG. 1;

FIG. 12 is a partial enlarged view of the region C in FIG. 11;

FIG. 13 is a partial enlarged view of the region Q in FIG. 1;

FIG. 14 is a partial enlarged view of the region C in FIG. 13;

FIG. 15 is a circuit diagram of a driving circuit in a display panel provided in an embodiment of the present application;

FIG. 16 is a schematic structural diagram of a display panel provided in an embodiment of the present application; and

FIG. 17 is a schematic structural diagram of a display device provided in an embodiment of the present application.

In the drawings:
1—display panel; 11—array base plate; 110—substrate; 111—first conductive layer; 1111—first signal line; 1112—second signal line; 1113—fifth signal line; 1114—sixth signal line; 112—second conductive layer; 1121—third signal line; 1122—fourth signal line; 1123—seventh signal line; 1124—eighth signal line; 12—first overlapping area; 13—second overlapping area; 14—third overlapping area; 15—fourth overlapping area; 16—pixel opening; 161—first pixel opening; 162—second pixel opening; 163—third pixel opening; 17—first extension portion; 18—second extension portion; 19—fifth overlapping area; 20—sixth overlapping area; 21—seventh overlapping area; 22—eighth overlapping area; 23—first semiconductor layer; 24—first metal layer; 25—second metal layer; 26—second semiconductor layer; 27—third metal layer; 28—fourth metal layer; 29—fifth metal layer; 30—first insulating layer; 31—second insulating layer; 32—third insulating layer; 33—fourth insulating layer; 34—fifth insulating layer; 35—sixth insulating layer; 36—light-emitting unit; 361—first electrode; 362—light-emitting functional layer; 363—second electrode; 37—isolation structure; 371—first isolation portion; 372—second isolation portion; 370—isolation opening; 100—driving module; 200—data writing module; 300—compensation module; 400—storage module; 500—first light-emitting control module; 600—second light-emitting control module; 700—first initialization module; 800—second initialization module; 900—third initialization module; Vref1—first reset signal line; Vref2—second reset signal line; ELVDD—first high-level signal line; ELVSS—first low-level signal line; S1—first scanning signal line; S2—second scanning signal line; S3—third scanning signal line; S4—fourth scanning signal line; EM—light-emitting control signal line; Data—data signal line; Vref3—third reset signal line; 2—display device.

### DETAILED DESCRIPTION

The features and exemplary embodiments of various aspects of the present application will be described in detail below. In the following detailed description, many specific details are proposed to provide a comprehensive understanding of the present application. However, it is obvious to those skilled in the art that the present application can be implemented without some of these specific details. The following description of the embodiments is only for providing a better understanding of the present application by showing examples of the present application.

It should be noted that, in the present application, relational terms such as first and second, etc. are only used to distinguish one entity or operation from another entity or operation, and do not necessarily require or imply that there is any such actual relationship or order between these entities or operations. Moreover, the terms “include”, “comprise” or any other variant thereof are intended to cover non-exclusive inclusion, so that a process, method, article or device including a series of elements includes not only those elements, but also other elements that are not explicitly listed, or includes elements inherent to such a process, method, article or device. In the absence of further restrictions, the elements defined by the sentence “include . . . ” do not exclude the existence of other identical elements in the process, method, article or device including the elements.

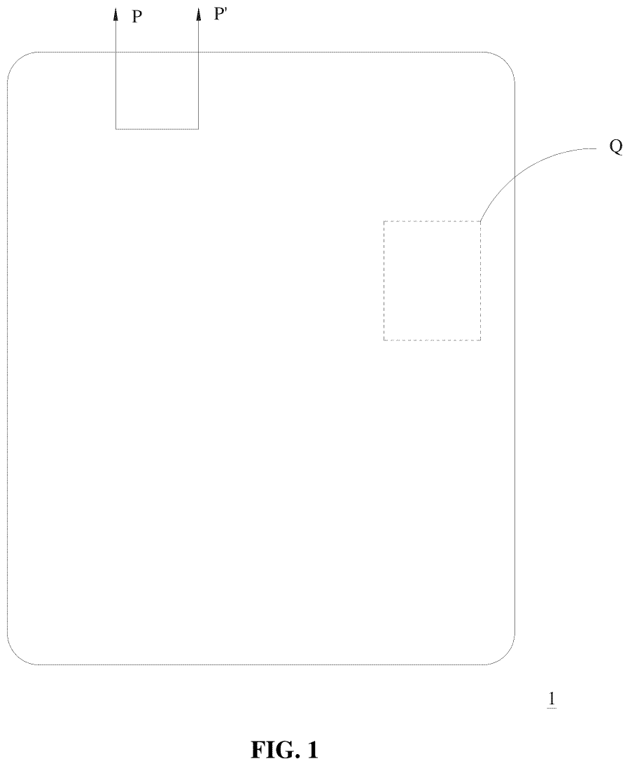

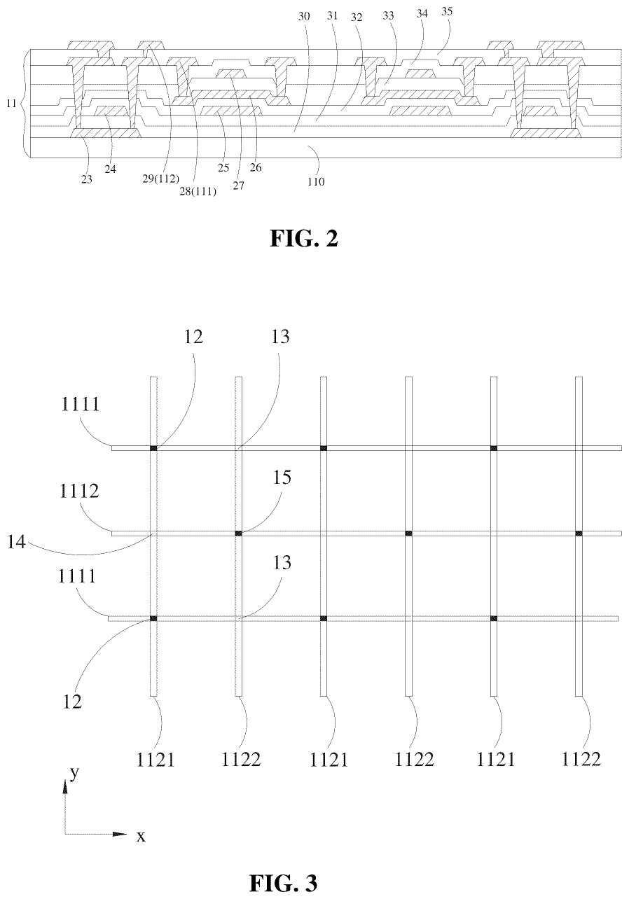

In order to better understand the present application, the display panel and display device 2 according to the embodiments of the present application are described in detail below in conjunction with FIGS. 1 to 17.

Referring to FIG. 1 to FIG. 3, an embodiment of the present application provides a display panel 1, which includes an array base plate 11 including a substrate 110 and a first conductive layer 111, an insulating layer, and a second conductive layer 112 stacked in sequence on a side of the substrate 110; the first conductive layer 111 includes a first signal line 1111 and a second signal line 1112 each extending along a first direction x, and the second conductive layer 112 includes a third signal line 1121 and a fourth signal line 1122 each extending along a second direction y, where the first direction x intersects with the second direction y; the first signal lines 1111 and the second signal lines 1112 are arranged along the second direction y, and the third signal lines 1121 and the fourth signal lines 1122 are arranged along the first direction x and transmit the same signal.

In a direction perpendicular to the substrate 110, a first signal line 1111 and a third signal line 1121 have a first overlapping area 12, a first signal line 1111 and a fourth signal line 1122 have a second overlapping area 13, a second signal line 1112 and a third signal line 1121 have a third overlapping area 14, and a second signal line 1112 and a fourth signal line 1122 have a fourth overlapping area 15; the first signal line 1111 and the third signal line 1121 are electrically connected in the first overlapping area 12, the first signal line 1111 and the fourth signal line 1122 are insulated in the second overlapping area 13 and/or the second signal line 1112 and the third signal line 1121 are insulated in the third overlapping area 14, and the second signal line 1112 and the fourth signal line 1122 are electrically connected in the fourth overlapping area 15.

The orthographic projections of the first overlapping area 12 and the fourth overlapping area 15 on the substrate 110 are located outside orthographic projections of pixel openings 16 on the substrate 110, and the orthographic projections of the second overlapping area 13 and the third overlapping area 14 on the substrate 110 are at least partially located within orthographic projections of pixel openings 16 on the substrate 110, where the pixel openings 16 are located on a side of the array base plate 11 in a direction from the substrate 110 to the insulating layer.

In the above-mentioned embodiments, the second conductive layer 112 is located on a side of the first conductive layer 111, specifically, may be located on an upper side of the first conductive layer 111, or a lower side of the first conductive layer 111, which is not specifically limited in the present application.

In the above-mentioned embodiments, the first overlapping area 12 is an area where the orthographic projections of the first signal line 1111 and the third signal line 1121 on the substrate 110 overlap. The second overlapping area 13 is an area where the orthographic projections of the first signal line 1111 and the third signal line 1121 on the substrate 110 overlap. The third overlapping area 14 is an area where the orthographic projections of the second signal line 1112 and the third signal line 1121 on the substrate 110 overlap. The fourth overlapping area 15 is an area where the orthographic projections of the second signal line 1112 and the fourth signal line 1122 on the substrate 110 overlap.

The pixel openings 16 are located on a side of the array base plate 11 in a direction from the substrate 110 to the insulating layer, that is, on a side of the second conductive layer 112 away from the substrate 110, and the pixel opening 16 is configured to accommodate and define the light-emitting unit.

In the above-mentioned display panel 1 provided in the present application, signals in the first signal lines 1111 and the third signal lines 1121 are the same, and the first signal lines 1111 and the third signal lines 1121 have and are electrically connected at first overlapping areas 12 formed at intersections thereof, so that the first signal lines 1111 and the third signal lines 1121 form a network structure. An orthographic projection of a first overlapping area 12 on the substrate 110 does not overlap an orthographic projection of a pixel opening 16 on the substrate 110, so that the first signal lines 1111 and the third signal lines 1121 may be electrically connected through vias at first overlapping areas 12; the vias are not located in the areas of the pixel openings 16, so that the presence of the vias may not cause the light-emitting units corresponding to the pixel openings 16 to display poorly caused by the unevenness of an upper film layer due to the vias.

The signals in the second signal lines 1112 and the fourth signal lines 1122 are the same, and the second signal lines 1112 and the fourth signal lines 1122 have and are electrically connected at fourth overlapping areas 15 formed at intersections thereof, so that the second signal lines 1112 and the fourth signal lines 1122 form a network structure. An orthographic projection of a fourth overlapping area 15 on the substrate 110 does not overlap an orthographic projection of a pixel opening 16 on the substrate 110, that is, the second signal lines 1112 and the fourth signal lines 1122 may be electrically connected through vias at fourth overlapping areas 15; the vias are not located in the areas of the pixel openings 16, so that the presence of the vias may not cause the light-emitting units corresponding to the pixel openings 16 to display poorly caused by the unevenness of an upper film layer due to the vias.

The first signal line 1111 and the fourth signal line 1122 have a second overlapping area 13, the second signal line 1112 and the third signal line 1121 have a third overlapping area 14, the first signal line 1111 and the fourth signal line 1122 are insulated in the second overlapping area 13, and/or, the second signal line 1112 and the third signal line 1121 are insulated in the third overlapping area 14, and the orthographic projections of the second overlapping area 13 and the third overlapping area 14 on the substrate 110 are at least partially located within orthographic projections of pixel openings 16 on the substrate 110, so that there is no need to arrange any via at the position(s) of the second overlapping area 13 and/or the third overlapping area 14, and the number of vias can be reduced to reduce the impact on the display yield of the light-emitting units corresponding to the pixel openings 16.

The above-mentioned display panel 1 provided in the present application realizes that the third signal line 1121 and the fourth signal line 1122 transmit the same signal, and the first signal line 1111 and the third signal line 1121 are electrically connected, and the second signal line 1112 and the fourth signal line 1122 are electrically connected, so that the orthographic projection of a via required for electrical connection on the substrate 110 is mostly or entirely located outside the orthographic projection of a pixel opening 16 on the substrate 110, thereby improving the problem of large color shift caused by the presence of the vias affecting the electrode flatness of the light-emitting units in the pixel openings 16, and improving the display quality of the display panel 1.

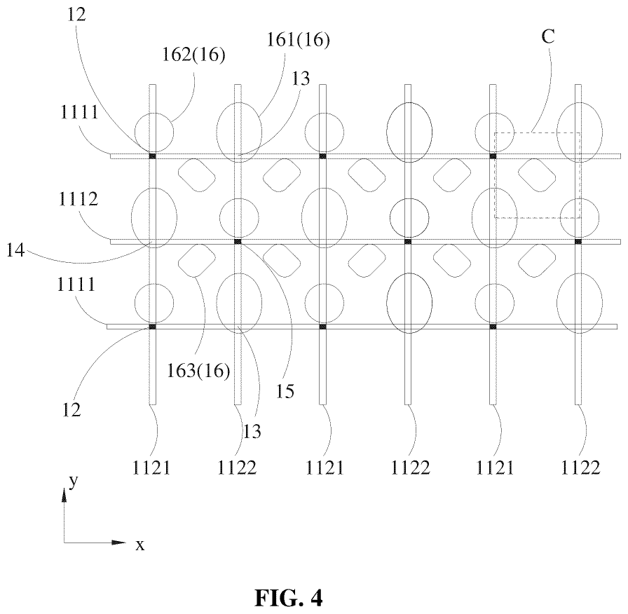

In a feasible embodiment, as shown in FIG. 4, the pixel openings 16 include first pixel openings 161, and the orthographic projections of a second overlapping area 13 and a third overlapping area 14 on the substrate 110 are at least partially located within orthographic projections of first pixel openings 161 on the substrate 110.

Further, the orthographic projections of a first overlapping area 12 and a fourth overlapping area 15 on the substrate 110 are located outside the orthographic projections of the first pixel openings 161 on the substrate 110.

In the above-mentioned embodiments, the pixel openings 16 are used to define the light-emitting units. The light-emitting units may include a red light-emitting unit, a green light-emitting unit and a blue light-emitting unit, where the blue light-emitting unit has a larger area and its color shift has the most serious impact on the yield of the display panel 1. The first pixel opening 161 may be used to accommodate the blue light-emitting unit.

The orthographic projections of the second overlapping area 13 and the third overlapping area 14 on the substrate 110 are arranged to be at least partially located within orthographic projections of the first pixel openings 161 on the substrate 110. Since there is no need to arrange any via at the position(s) of the second overlapping area 13 and/or the third overlapping area 14, on the one hand, the influence of the second overlapping area 13 and/or the third overlapping area 14 on the flattening of the upper film layer can be reduced to ensure the yield of the blue light-emitting unit and improve the problem of poor display of the blue light-emitting units corresponding to the first pixel openings 161 caused by the unevenness of an upper film layer due to the vias.

On the other hand, since the first pixel opening 161 is relatively large, the orthographic projections of the second overlapping area 13 and the third overlapping area 14 on the substrate 110 are arranged to be at least partially located within orthographic projections of the first pixel openings 161 on the substrate 110, so as to simplify the wiring difficulty and ensure the wiring spacing. In a feasible embodiment, the display panel 1 may also include a pixel definition layer formed on a side away from the substrate 110 of the one of the first conductive layer 111 and the second conductive layer 112 that is farther from the substrate 110, which may be used to define the pixel opening 16.

In a feasible embodiment, as shown in FIG. 4, the pixel openings 16 also includes a second pixel opening 162, the first pixel openings 161 and the second pixel openings 162 are alternately arranged along the second direction y, and the first pixel openings 161 and the second pixel openings 162 are also alternately arranged along the first direction x, and the first overlapping area 12 and the fourth overlapping area 15 each are located between adjacent two of the first pixel opening 161 and the second pixel opening 162 along the second direction y. A via for electrically connecting the first signal line 1111 with the third signal line 1121 and a via for electrically connecting the second signal line 1112 with the fourth signal line 1122 are arranged between the first pixel opening 161 and the second pixel opening 162, which can reduce the adverse effects on the light-emitting units of different colors caused by the unevenness of an upper film layer due to the vias, so as to improve the display effect.

Specifically, the second pixel opening 162 can be used to accommodate the red light-emitting unit.

In a feasible embodiment, as shown in FIG. 4, a plurality of first pixel openings 161 and second pixel openings 162 are alternately arranged along the second direction y to form a first pixel column. In adjacent two of the first pixel columns, the first overlapping area 12 and the third overlapping area 14 are located in one of the first pixel columns, and the second overlapping area 13 and the fourth overlapping area 15 are located in the other first pixel column; thus, such an arrangement can be realized that there are one of the first overlapping area 12 and the fourth overlapping area 15 and one of the second overlapping area 13 and the third overlapping area 14 in each pixel column. The first overlapping area 12 and the fourth overlapping area 15 are used for achieving electrical connection, and the second overlapping area 13 and/or the third overlapping area 14 are insulated. Therefore, in the above embodiments, the first overlapping area 12 and the fourth overlapping area 15 used for achieving electrical connection, and the second overlapping areas 13 and/or the third overlapping areas 14 used for insulation are alternately arranged along the first direction x and the second direction y, thereby improving the uniformity of the display panel 1.

In a feasible embodiment, as shown in FIG. 4, the pixel openings 16 further includes a third pixel opening 163, and a plurality of third pixel openings 163 are arranged along the second direction y to form a second pixel column, and the first pixel columns and the second pixel columns are alternately arranged along the first direction x.

In the above-mentioned embodiments, the third pixel opening 163 may be used to form a green light-emitting unit.

In a feasible embodiment, as shown in FIG. 4, two first pixel openings 161 and two second pixel openings 162 are arranged around the third pixel opening 163, and the two first pixel openings 161 and the two second pixel openings 162 are alternately distributed around the third pixel opening 163. The above pixel arrangement can achieve a better light mixing effect.

In the above-mentioned pixel arrangement, the display panel 1 includes a plurality of dummy quadrilaterals C arranged in rows and columns, and two opposite vertices in each dummy quadrilateral C each coincide with a center of the first pixel opening 161, and the other two opposite vertices each coincide with a center of the second pixel opening 162.

In the above-mentioned pixel arrangement, the orthographic projection of the first signal line 1111 on the substrate 110 does not overlap an orthographic projection of the second pixel opening 162 or the third pixel opening 163 on the substrate 110, and the orthographic projection of the first signal line 1111 on the substrate 110 passes through the orthographic projection of the first pixel opening 161 on the substrate 110 along the first direction x.

The orthographic projection of the second signal line 1112 on the substrate 110 does not overlap the orthographic projection of the second pixel opening 162 or the third pixel opening 163 on the substrate 110, and the orthographic projection of the second signal line 1112 on the substrate 110 passes through the orthographic projection of the first pixel opening 161 on the substrate 110 along the first direction x.

The orthographic projection of the third signal line 1121 on the substrate 110 does not overlap the orthographic projection of the third pixel opening 163 on the substrate 110, and the orthographic projection of the third signal line 1121 on the substrate 110 passes through the orthographic projection of the first pixel opening 161 on the substrate 110 and the orthographic projection of the second pixel opening 162 on the substrate 110 along the second direction y. The orthographic projection of the fourth signal line 1122 on the substrate 110 does not overlap the orthographic projection of the third pixel opening 163 on the substrate 110, and the orthographic projection of the fourth signal line 1122 on the substrate 110 passes through the orthographic projection of the first pixel opening 161 on the substrate 110 and the orthographic projection of the second pixel opening 162 on the substrate 110 along the second direction y.

In the above-mentioned embodiments, the orthographic projection of the first signal line 1111 on the substrate 110 does not overlap the orthographic projection of the second pixel opening 162 or the third pixel opening 163 on the substrate 110, and the orthographic projection of the first signal line 1111 on the substrate 110 passes through the orthographic projection of the first pixel opening 161 on the substrate 110 along the first direction x. The orthographic projection of the third signal line 1121 on the substrate 110 does not overlap the orthographic projection of the third pixel opening 163 on the substrate 110 and passes through the orthographic projection of the first pixel opening 161 on the substrate 110 and the orthographic projection of the second pixel opening 162 on the substrate 110 along the second direction y.

An orthographic projection of a first signal line 1111 or a second signal line 1112 on the substrate 110 may pass through the orthographic projection of the same dummy quadrilateral C on the substrate 110, and the orthographic projection of the first signal line 1111 on the substrate 110 does not overlap the orthographic projection of the second pixel opening 162 or the third pixel opening 163 on the substrate 110, and the orthographic projection of the third signal line 1121 on the substrate 110 passes through the orthographic projection of the first pixel opening 161 on the substrate 110 and the orthographic projection of the second pixel opening 162 on the substrate 110 along the second direction y, so that the first overlapping area 12 formed by an overlapping between the first signal line 1111 and the third signal line 1121 may be located between the second pixel opening 162 and the first pixel opening 161 along the second direction y, and the orthographic projection of the first overlapping area 12 on the substrate 110 does not overlap the orthographic projection of the pixel opening 16 on the substrate 110, and the first signal line 1111 and the third signal line 1121 are arranged to be electrically connected at a position of the first overlapping area 12 to prevent the flatness of the electrode of the light-emitting unit 36 corresponding to the pixel opening 16 from being affected, so as to improve the color shift.

In the above-mentioned embodiments, the orthographic projection of the second signal line 1112 on the substrate 110 does not overlap the orthographic projection of the second pixel opening 162 or the third pixel opening 163 on the substrate 110, and the orthographic projection of the second signal line 1112 on the substrate 110 passes through the orthographic projection of the first pixel opening 161 on the substrate 110 along the first direction x. The orthographic projection of the fourth signal line 1122 on the substrate 110 does not overlap the orthographic projection of the third pixel opening 163 on the substrate 110, and the orthographic projection of the fourth signal line 1122 on the substrate 110 passes through the orthographic projection of the first pixel opening 161 on the substrate 110 and the orthographic projection of the second pixel opening 162 on the substrate 110 along the second direction y.

An orthographic projection of a first signal line 1111 or a second signal line 1112 on the substrate 110 may pass through the orthographic projection of the same dummy quadrilateral C on the substrate 110, and the orthographic projection of the second signal line 1112 on the substrate 110 does not overlap the orthographic projection of the second pixel opening 162 or the third pixel opening 163 on the substrate 110, and only overlaps the orthographic projection of the first pixel opening 161 on the substrate 110, so that the orthographic projection of the fourth signal line 1122 on the substrate 110 passes through the orthographic projections of the first pixel opening 161 and the second pixel opening 162 on the substrate 110 along the second direction y, and then a fourth overlapping area 15 can be formed with the second signal line 1112, and the orthographic projection of the fourth overlapping area 15 on the substrate 110 is located between the orthographic projections of the second pixel opening 162 and the first pixel opening 161 on the substrate 110, so that the orthographic projection of the fourth overlapping area 15 on the substrate 110 does not overlap the orthographic projection of the pixel opening 16 on the substrate 110, and the second signal line 1112 and the fourth signal line 1122 are arranged to be electrically connected at the position of the second overlapping area 13 to prevent the flatness of the electrode of the light-emitting unit 36 corresponding to the pixel opening 16 from being affected, so as to improve the color shift.

In a feasible embodiment, as shown in FIG. 4, the first signal lines 1111 and the fourth signal lines 1122 are insulated in the second overlapping areas 13, and the second signal lines 1112 and the third signal lines 1121 are insulated in the third overlapping areas 14.

In the above-mentioned embodiments, the signal lines in the second overlapping area 13 and the third overlapping area 14 are insulated. Therefore, in the display panel 1, the orthographic projections of the first overlapping area 12 and the fourth overlapping area 15 for electrical connection on the substrate 110 each are located outside the pixel openings 16, and the signal lines are insulated in the second overlapping area 13 and the third overlapping area 14 of which the orthographic projections on the substrate 110 overlap the orthographic projections of the pixel openings 16 on the substrate 110, so that the vias for electrical connection can completely avoid the areas of the pixel openings 16, thereby minimizing the influence of the vias for electrical connection on the color shift of the light-emitting unit in the pixel opening 16, thereby improving the display quality.

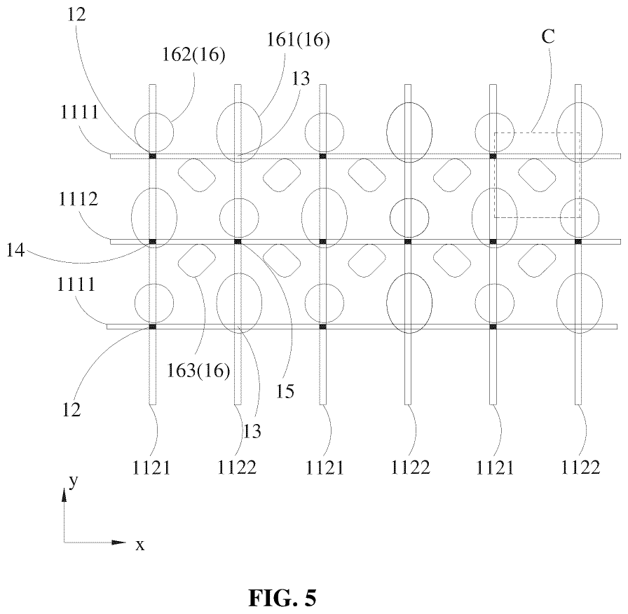

In another feasible embodiment, as shown in FIG. 5, the first signal lines 1111 and the fourth signal lines 1122 are insulated in the second overlapping areas 13, and the second signal lines 1112 and the third signal lines 1121 are electrically connected in the third overlapping areas 14. Thus, the connection points where the second signal lines 1112 and the third signal lines 1121 connect can be increased, thereby further improving the electrical connection effect between the second signal line 1112 and the third signal line 1121.

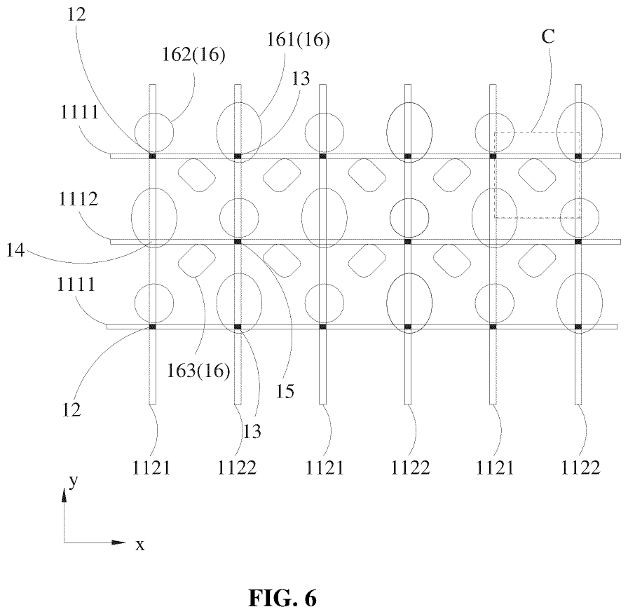

In another feasible embodiment, as shown in FIG. 6, the first signal lines 1111 and the fourth signal lines 1122 are electrically connected in the second overlapping areas 13, and the second signal lines 1112 and the third signal lines 1121 are insulated in the third overlapping areas 14. Thus, the connection points where the first signal lines 1111 and the fourth signal lines 1122 connect can be increased, thereby further improving the electrical connection effect between the first signal line 1111 and the fourth signal line 1122.

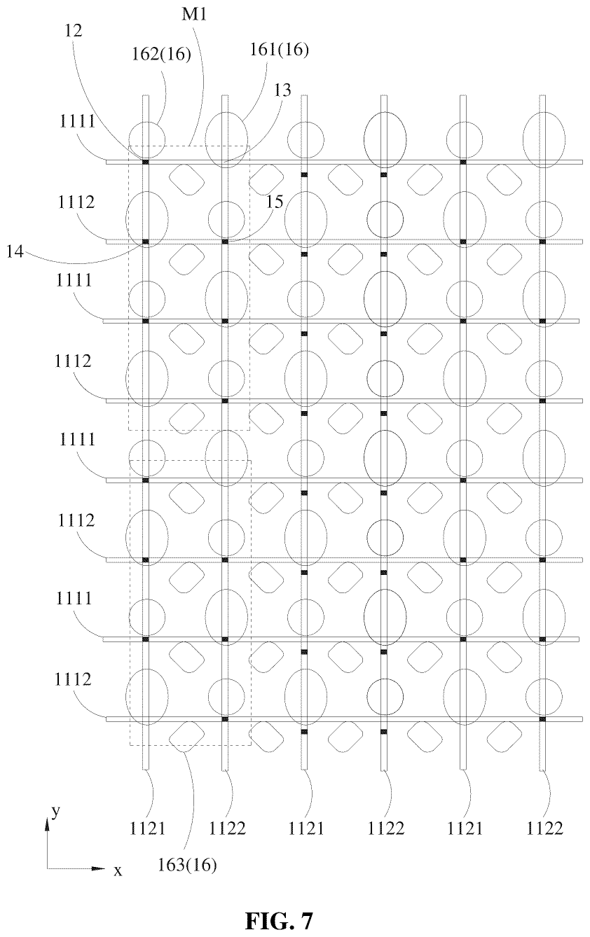

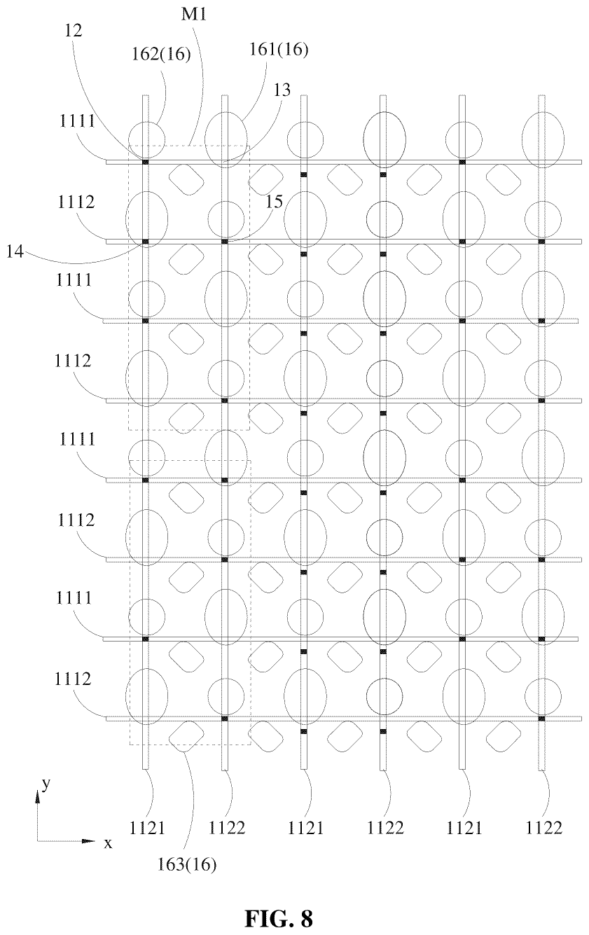

In another feasible implementation, as shown in FIG. 7 and FIG. 8, the first signal lines 1111 and the fourth signal lines 1122 are insulated in some of the second overlapping areas 13 and electrically connected in some preset ones of the second overlapping areas 13, and the second signal lines 1112 and the third signal lines 1121 are insulated in some of the third overlapping areas 14 and electrically connected in some preset ones of the third overlapping areas 14. Thus, the connection points where the first signal lines 1111 and the fourth signal lines 1122 connect and the connection points where the second signal lines 1112 and the third signal lines 1121 connect may be increased, thereby further improving the electrical connection effect between the second signal line 1112 and the third signal line 1121, and further improving the electrical connection effect between the first signal line 1111 and the fourth signal line 1122.

In the above-mentioned embodiments, as shown in FIG. 7, a sum of a number of parts of preset of the second overlapping areas 13 and parts of preset of the third overlapping areas 14 is half of a sum of a number of the second overlapping areas 13 and the third overlapping areas 14, or as shown in FIG. 8, a sum of the number of parts of preset of the second overlapping areas 13 and parts of preset of the third overlapping areas 14 is one quarter of a sum of the number of the second overlapping areas 13 and the third overlapping areas 14. Thus, the connection points can be reduced by half or three quarters, which can improve the color shift problem to a certain extent.

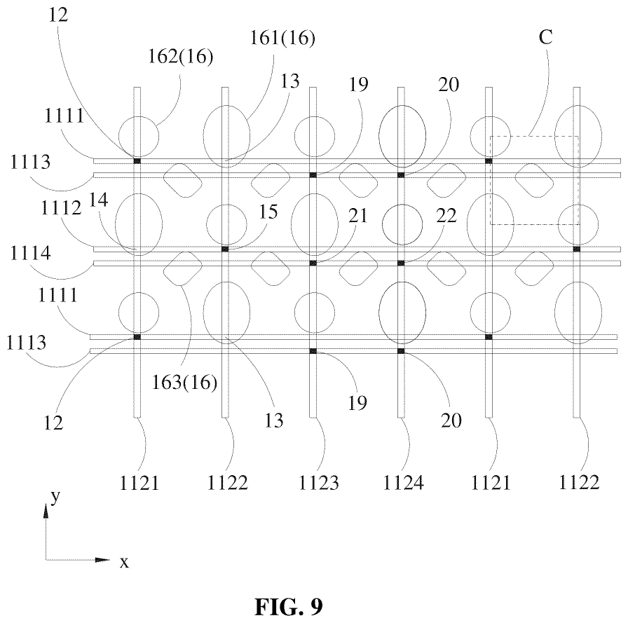

In a feasible embodiment, as shown in FIG. 9, the first conductive layer 111 also includes a fifth signal line 1113 and a sixth signal line 1114 each extending along the first direction x, and the second conductive layer 112 also includes a seventh signal line 1123 and an eighth signal line 1124 each extending along the second direction y, the fifth signal lines 1113 and the sixth signal lines 1114 are arranged along the second direction y, the seventh signal lines 1123 and the eighth signal lines 1124 are arranged along the first direction x, and the seventh signal lines 1123 and the eighth signal lines 1124 transmit the same signal.

In the above-mentioned embodiments, the third signal line 1121 and the fourth signal line 1122 transmit the same signal, and cross with the first signal line 1111 and the second signal line 1112 to form a network for transmitting one signal; the seventh signal line 1123 and the eighth signal line 1124 transmit the same signal, and cross with the fifth signal line 1113 and the sixth signal line 1114 to form a network for transmitting another signal.

In a feasible embodiment, as shown in FIG. 9, the third signal lines 1121 and the fourth signal lines 1122 are arranged adjacently one another along the first direction x, and the seventh signal lines 1123 and the eighth signal lines 1124 are arranged adjacently one another along the first direction x; each of the fifth signal lines 1113 is located between one of the first signal lines 1111 and one of the second signal lines 1112 which ones are adjacent to each other, and each of the sixth signal lines 1114 is located between one of the first signal lines 1111 and one of the second signal lines 1112 which ones are adjacent to each other, and one of the first signal lines 1111 or one of the second signal lines 1112 is arranged between each of the fifth signal lines 1113 and each of the sixth signal lines 1114 which are adjacent one another.

In the above-mentioned embodiments, the third signal lines 1121 and the fourth signal lines 1122 are arranged adjacently one another along the first direction x, and the seventh signal lines 1123 and the eighth signal lines 1124 are arranged adjacently one another along the first direction x; therefore, it can be ensured that the third signal lines 1121 and the fourth signal lines 1122 can be allowed to form networks, respectively, while being insulated at the second overlapping areas 13 and the third overlapping areas 14.

In a feasible embodiment, as shown in FIG. 9, the orthographic projection of the fifth signal line 1113 on the substrate 110 does not overlap the orthographic projection of the first pixel opening 161 or the second pixel opening 162 on the substrate 110, and the orthographic projection of the first signal line 1111 on the substrate 110 passes through the orthographic projection of the third pixel opening 163 on the substrate 110 along the first direction x.

The orthographic projection of the sixth signal line 1114 on the substrate 110 does not overlap the orthographic projection of the first pixel opening 161 or the second pixel opening 162 on the substrate 110, and the orthographic projection of the sixth signal line 1114 on the substrate 110 passes through the orthographic projection of the third pixel opening 163 on the substrate 110 along the first direction x.

The orthographic projection of the seventh signal line 1123 on the substrate 110 does not overlap the orthographic projection of the third pixel opening 163 on the substrate 110, and the orthographic projection of the seventh signal line 1123 on the substrate 110 passes through the orthographic projection of the first pixel opening 161 on the substrate 110 and the orthographic projection of the second pixel opening 162 on the substrate 110 along the second direction y.

The orthographic projection of the eighth signal line 1124 on the substrate 110 does not overlap the orthographic projection of the third pixel opening 163 on the substrate 110, and the orthographic projection of the eighth signal line 1124 on the substrate 110 passes through the orthographic projection of the first pixel opening 161 on the substrate 110 and the orthographic projection of the second pixel opening 162 on the substrate 110 along the second direction y.

In the above-mentioned embodiments, since the fifth signal line 1113 and the sixth signal line 1114 do not pass through the first pixel opening 161 and the second pixel opening 162, the electrical connection positions of the fifth signal line 1113, the sixth signal line 1114, the seventh signal line 1123 and the eighth signal line 1124 may be arranged between the first pixel opening 161 and the second pixel opening 162 arranged along the second direction y, so as not to affect the light-emitting yield of the light-emitting unit 36 in the pixel opening 16.

In a feasible embodiment, as shown in FIG. 9, a fifth signal line 1113 and a seventh signal line 1123 have a fifth overlapping area 19, a fifth signal line 1113 and an eighth signal line 1124 have a sixth overlapping area 20, a sixth signal line 1114 and a seventh signal line 1123 have a seventh overlapping area 21, and a sixth signal line 1114 and an eighth signal line 1124 have an eighth overlapping area 22. The fifth signal line 1113 and the seventh signal line 1123 are electrically connected in the fifth overlapping area 19, the sixth signal line 1114 and the eighth signal line 1124 are electrically connected in the eighth overlapping area 22, and/or the fifth signal line 1113 and the eighth signal line 1124 are electrically connected in the sixth overlapping area 20, and the sixth signal line 1114 and the seventh signal line 1123 are electrically connected in the seventh overlapping area 21.

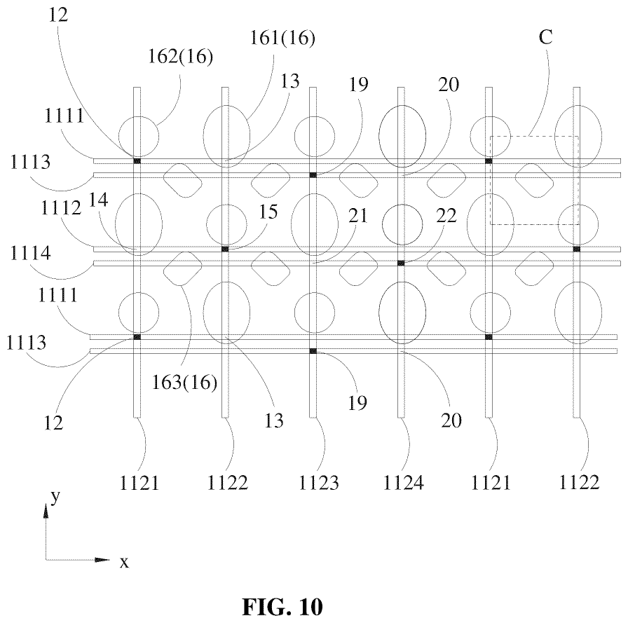

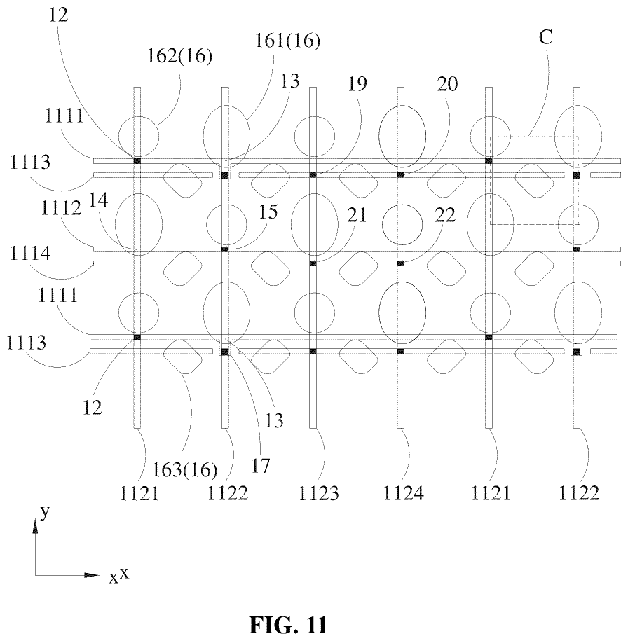

In the above embodiments, as shown in FIG. 9, the fifth overlapping areas 19, the sixth overlapping areas 20, the seventh overlapping areas 21, and the eighth overlapping areas 22 all may be electrically connected overlapping areas, or some are insulated overlapping areas and the other are electrically connected overlapping areas, as long as it is ensured that the fifth signal lines 1113, the eighth signal lines 1124, the sixth signal lines 1114, and the seventh signal lines 1123 form a network, specifically one network or two networks. Specifically, as shown in FIG. 10, the fifth signal lines 1113 and the seventh signal lines 1123 may be electrically connected in the fifth overlapping areas 19, the fifth signal lines 1113 and the eighth signal lines 1124 may be insulated in the sixth overlapping areas 20, the sixth signal lines 1114 and the seventh signal lines 1123 may be insulated in the seventh overlapping areas 21, and the sixth signal lines and the eighth signal lines 1124 may be electrically connected in the eighth overlapping areas 22.

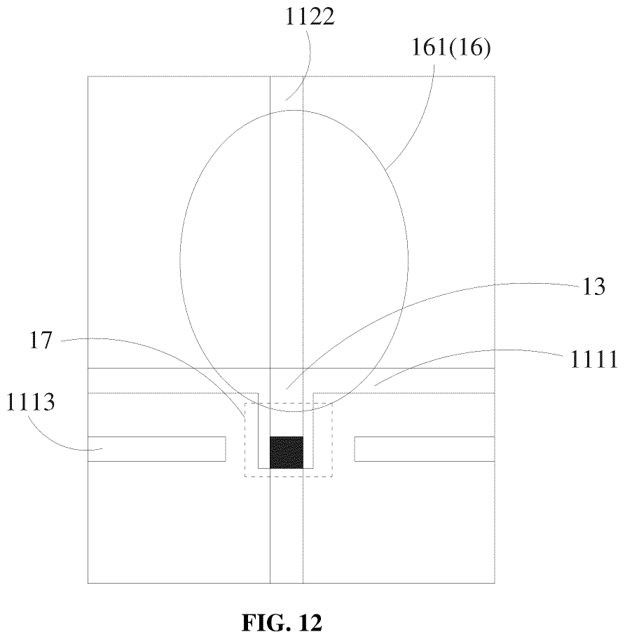

In a feasible embodiment, as shown in FIG. 11 and FIG. 12, the first signal line 1111 further includes a first extension portion 17 connected to the second overlapping area 13 and arranged with the second overlapping area 13 along the second direction y, and the orthographic projection of the first extension portion 17 on the substrate 110 is at least partially located outside the orthographic projection of the first pixel opening 161 on the substrate 110. The first extension portion 17 is electrically connected to the fourth signal line 1122 through a first through hole. The orthographic projection of the first through hole on the substrate 110 does not overlap the orthographic projection of the first pixel opening 161 on the substrate 110.

In the above-mentioned embodiments, the first through hole may be provided on the first extension portion 17 to realize the electrical connection between the first signal line 1111 and the fourth signal line 1122. Specifically, the first through hole is formed on the first extension portion 17 connected to the second overlapping area 13, so that an overlapping area between the first signal line 1111 and the fourth signal line 1122 may be increased. The arrangement of the first extension portion 17 allows a position where the first signal line 1111 and the fourth signal line 1122 overlap and form the first through hole to be moved to the outside of the orthographic projection of the pixel opening 16 on the substrate 110 to realize the electrical connection between the first signal line 1111 and the fourth signal line 1122, so that the first through hole may not affect the color shift of the light-emitting unit 36 in the pixel opening 16.

In the above-mentioned embodiments, the fifth signal line 1113 includes a first partition area for accommodating the first extension portion 17 at least partially located in the first partition area.

Since the fifth signal line 1113 is close to the first signal line 1111, a first partition area is provided on the fifth signal line 1113 to accommodate the first extension portion 17, so as to provide conditions for arranging a first through hole on the first extension portion 17.

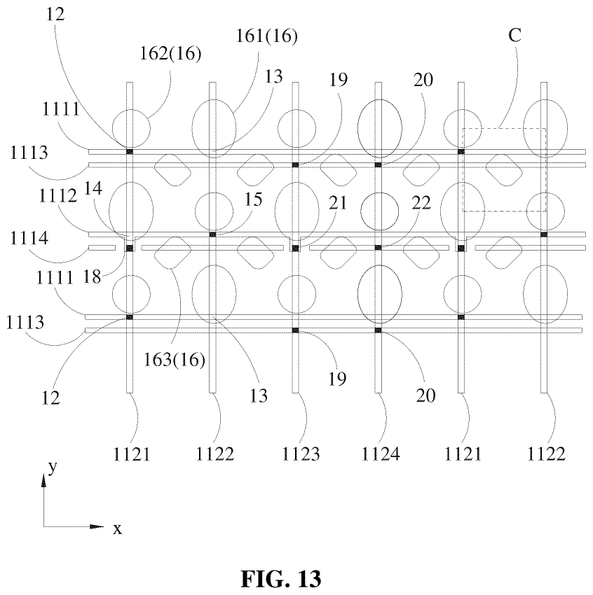

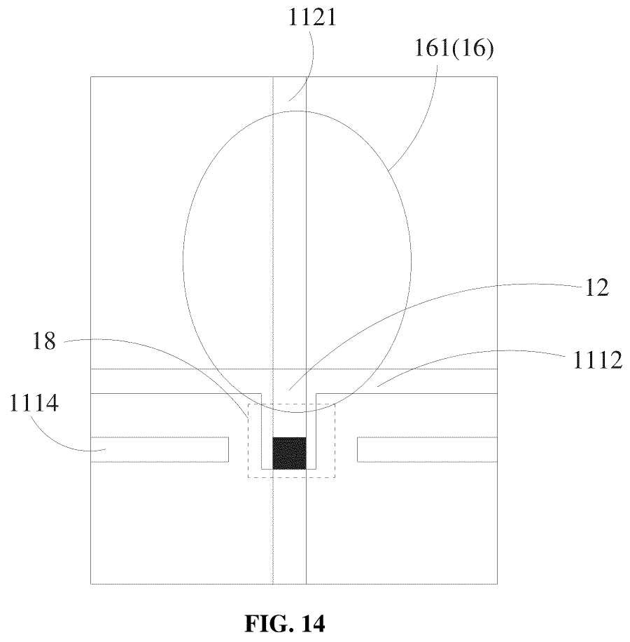

In a feasible embodiment, as shown in FIG. 13 and FIG. 14, the second signal line 1112 further includes a second extension portion 18 connected to the third overlapping area 14, and arranged with the third overlapping area 14 along the second direction y, and the orthographic projection of the second extension portion 18 on the substrate 110 is at least partially located outside the orthographic projection of the first pixel opening 161 on the substrate 110. The second extension portion 18 is electrically connected to the third signal line 1121 through a second through hole. The orthographic projection of the second through hole on the substrate 110 does not overlap the orthographic projection of the first pixel opening 161 on the substrate 110.

In the above-mentioned embodiments, the second through hole may be provided on the second extension portion 18 to realize the electrical connection between the second signal line 1112 and the third signal line 1121. Specifically, the second through hole is formed on the second extension portion 18 connected to the third overlapping area 14, so that an overlapping area between the second signal line 1112 and the third signal line 1121 may be increased. The arrangement of the second extension portion 18 allows a position where the second signal line 1112 and the third signal line 1121 overlap and form the second through hole to be moved to the outside of the orthographic projection of the pixel opening 16 on the substrate 110 to realize the electrical connection between the second signal line 1112 and the third signal line 1121, so that the second through hole may not affect the color shift of the light-emitting unit 36 in the pixel opening 16.

In the above-mentioned embodiments, the sixth signal line 1114 includes a second partition area for accommodating the second extension portion 18 at least partially located in the second partition area.

Since the sixth signal line 1114 is close to the second signal line 1112, a second partition area is provided on the sixth signal line 1114 to accommodate the second extension portion 18, so as to provide conditions for arranging the second through hole on the second extension portion 18.

In a feasible embodiment, the display panel further includes a first high-level signal line located in the second conductive layer 112 and extending along the second direction y, part of an orthographic projection of the first high-level signal line on the substrate 110 located within the orthographic projections of the second pixel opening 162 and the first pixel opening 161 on the substrate 110 is symmetrical with respect to a symmetry axis parallel to the second direction y.

Thus, the symmetry of the first electrode 361 of the light-emitting unit 36 may be higher, so as to improve the color shift phenomenon and enhance the display quality of the display panel 1.

In a feasible embodiment, the second conductive layer 112 is located on a side of the first conductive layer 111 away from the substrate 110.

In a feasible implementation, the signals in the first signal line 1111 and the fifth signal line 1113 are different.

Specifically, the first signal line 1111 has a first reset signal, that is, the first signal line 1111, the second signal line 1112, the third signal line 1121 and the fourth signal line 1122 are all first reset signal lines Vref1, and the fifth signal line 1113 has a second reset signal, that is, the fifth signal line 1113, the sixth signal line 1114, the seventh signal line 1123 and the eighth signal line 1124 are all second reset signal lines Vref2.

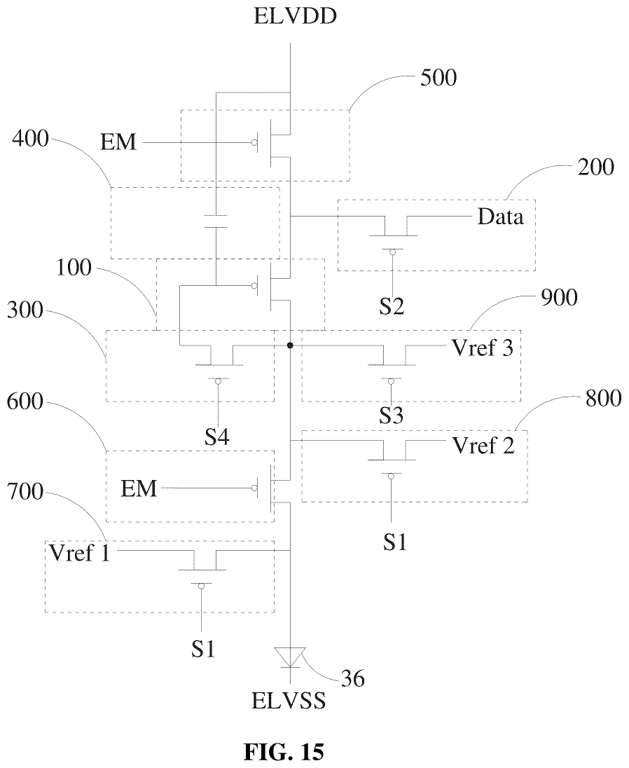

Specifically, as shown in FIG. 15, the drive circuit is electrically connected to at least one light-emitting unit 36 and includes a first light-emitting control module 500, a first initialization module 700 and a second initialization module 800. A control end of the second initialization module 800 is electrically connected to the first scanning signal line S1, a first end of the second initialization module 800 is electrically connected to the second reset signal line Vref2, and a second end of the second initialization module 800 is electrically connected to a first end of the first light-emitting control module 500. A control end of the first initialization module 700 is electrically connected to the first scanning signal line S1, a first end of the first initialization module 700 is electrically connected to the first reset signal line Vref1, and a second end of the first initialization module 700 is electrically connected to a second end of the first light-emitting control module 500 and the light-emitting unit 36. The control end of the first light-emitting control module 500 is electrically connected to the light-emitting control signal line EM, the first end of the first light-emitting control module 500 is electrically connected to the second initialization module 800, and the second end of the first light-emitting control module 500 is electrically connected to the first initialization module 700 and the light unit 36.

The driving circuit also includes a driving module 100, a data writing module 200, a compensation module 300, a storage module 400, a second light-emitting control module 600, and a third initialization module 900. The display panel 1 also includes a first high-level signal line ELVDD, a first low-level signal line ELVSS, a second scanning signal line S2, a first scanning signal line S1, a third scanning signal line S3, a fourth scanning signal line S4S4, a light-emitting control signal line EM, a data signal line Data, and a third reset signal line Vref3.

Herein the control end of the second light-emitting control module 600 is connected to the light-emitting control signal line EM, the first end of the second light-emitting control module 600 is connected to the first high-level signal line ELVDD and the first end of the storage module 400, the second end of the second light-emitting control module 600 is connected to the second end of the data writing module 200 and the first end of the driving module 100.

The first end of the storage module 400 is connected to the first high-level signal line ELVDD and the first end of the second light-emitting control module 600, and the second end of the storage module 400 is connected to the first end of the compensation module 300 and the control end of the driving module 100.

The control end of the data writing module 200 is electrically connected to the second scanning signal line S2, the first end of the data writing module 200 is electrically connected to the data signal line Data, and the second end of the data writing module 200 is connected to the first end of the driving module 100 and the second end of the second light-emitting control module 600.

The control end of the compensation module 300 is connected to the fourth scanning signal line S4, the first end of the compensation module 300 is connected to the second end of the storage module 400 and the control end of the driving module 100, and the second end of the compensation module 300 is electrically connected to the first node N.

The control end of the driving module 100 is electrically connected to the second end of the storage module 400 and the first end of the compensation module 300, the first end of the driving module 100 is connected to the second end of the data writing module 200 and the second end of the second light-emitting control module 600, and the second end of the driving module 100 is electrically connected to the first node N.

The control end of the first light-emitting control module 500 is electrically connected to the light-emitting control signal line EM, the first end of the first light-emitting control module 500 is electrically connected to the second initialization module 800 and the first node N, and the second end of the first light-emitting control module 500 is electrically connected to the first initialization module 700 and the light-emitting unit 36.

The control end of the second initialization module 800 is electrically connected to the first scanning signal line S1, the first end of the second initialization module 800 is electrically connected to the second reset signal line Vref2, the second end of the second initialization module 800 is electrically connected to the first end of the first light-emitting control module 500 and the first node N.

The control end of the first initialization module 700 is electrically connected to the first scanning signal line S1, the first end of the first initialization module 700 is electrically connected to the first reset signal line Vref1, and the second end of the first initialization module 700 is electrically connected to the second end of the first light-emitting control module 500 and the light-emitting unit 36.

The control end of the third initialization module 900 is electrically connected to the third scanning signal line S3, the first end of the third initialization module 900 is electrically connected to the third reset signal line Vref3, and the second end of the third initialization module 900 is electrically connected to the second end of the second initialization module 800 and the first node N.

The light-emitting unit 36 includes a first electrode 361 and a second electrode 363, the first electrode 361 is electrically connected to the second end of the first initialization module 700 and the second end of the first light-emitting control module 500, and the second electrode 363 is electrically connected to the first low-level signal line ELVSS.

In the above-mentioned embodiments, the first initialization module 700 is configured to reset the first electrode 361 of the light-emitting unit 36, the second initialization module 800 is configured to reset the second end of the driving module 100, and the third initialization module 900 is configured to reset the control end of the driving module 100, which are conducive to improving the display quality.

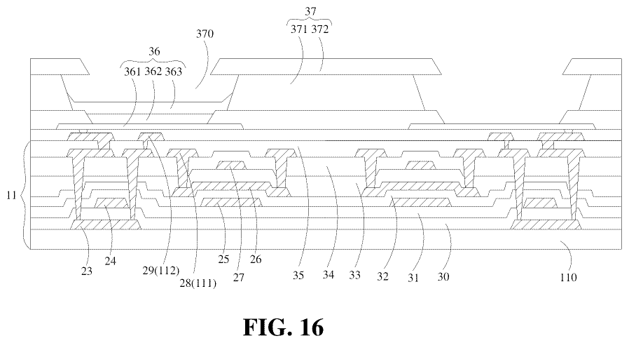

The present application also provides a display panel 1, as shown in FIG. 16, the display panel 1 includes an array base plate 11, the array base plate 11 includes a substrate 110 and a first semiconductor layer 23, a first metal layer 24, a second metal layer 25, a second semiconductor layer 26, a third metal layer 27, a fourth metal layer 28 and a fifth metal layer 29 stacked in a direction away from the substrate 110, where the array base plate 11 comprises a first type transistor, a second type transistor and a capacitor, the first semiconductor layer 23 is configured to form a source region, a drain region and a channel region of the first type transistor, the first metal layer 24 is configured to form a gate of the first type transistor and a first polar plate of the capacitor, the second metal layer 25 is configured to form a bottom gate of the second type transistor, the second semiconductor layer 26 is configured to form a source region, a drain region and a channel region of the second type transistor, the third metal layer 27 is configured to form a top gate of the second type transistor, and the fourth metal layer 28 is configured to form sources and drains of the first type transistor and the second type transistor.

where one of the first metal layer 24, the second metal layer 25, the third metal layer 27 and the fourth metal layer 28 is formed with a first signal line 1111 and a second signal line 1112 extending along a first direction x and arranged in the second direction y, and the fifth metal layer 29 is formed with a third signal line 1121 and a fourth signal line 1122 extending along the second direction y and arranged in the first direction x, the first direction x intersects with the second direction y, and the third signal lines 1121 and the fourth signal lines 1122 transmit a same signal.

In a direction perpendicular to the substrate 110, a first signal line 1111 and a third signal line 1121 have a first overlapping area 12, a first signal line 1111 and a fourth signal line 1122 have a second overlapping area 13, and a second signal line 1112 and a third signal line 1121 have a third overlapping area 14, and a second signal line 1112 and a fourth signal line 1122 have a fourth overlapping area 15, the first signal line 1111 and the third signal line 1121 are electrically connected in the first overlapping area 12, the first signal line 1111 and the fourth signal line 1122 are insulated in the second overlapping area 13 and/or the second signal line 1112 and the third signal line 1121 are insulated in the third overlapping area 14, the second signal line 1112 and the fourth signal line 1122 are electrically connected in the fourth overlapping area 15, orthographic projections of the first overlapping area 12 and the fourth overlapping area 15 on the substrate 110 are located outside orthographic projections of pixel openings 16 on the substrate 110, and orthographic projections of the second overlapping area 13 and the third overlapping area 14 on the substrate 110 are at least partially located within orthographic projections of pixel openings 16 on the substrate 110.

In the above-mentioned display panel 1 provided in the present application, the signals in the first signal lines 1111 and the third signal lines 1121 are the same, and the first signal lines 1111 and the third signal lines 1121 have and are electrically connected at first overlapping areas 12 formed at intersections thereof, so that the first signal lines 1111 and the third signal lines 1121 form a network structure. An orthographic projection of a first overlapping area 12 on the substrate 110 does not overlap an orthographic projection of a pixel opening 16 on the substrate 110, so that the first signal lines 1111 and the third signal lines 1121 may be electrically connected through vias at first overlapping areas 12, the vias are not located in the areas of the pixel openings 16, so that the presence of the vias may not cause the light-emitting units 36 corresponding to the pixel openings 16 to display poorly caused by the unevenness of an upper film layer due to the vias.

The signals in the second signal lines 1112 and the fourth signal lines 1122 are the same, and the second signal lines 1112 and the fourth signal lines 1122 have and are electrically connected at fourth overlapping areas 15 formed at intersections thereof, so that the second signal lines 1112 and the fourth signal lines 1122 form a network structure. An orthographic projection of a fourth overlapping area 15 on the substrate 110 does not overlap an orthographic projection of a pixel opening 16 on the substrate 110, that is, the second signal lines 1112 and the fourth signal lines 1122 may be electrically connected through vias at fourth overlapping areas 15, and the vias are not located in the areas the pixel openings 16, so that the presence of the vias may not cause the light-emitting units 36 corresponding to the pixel openings 16 to display poorly caused by the unevenness of an upper film layer due to the vias.

The first signal line 1111 and the fourth signal line 1122 have a second overlapping area 13, the second signal line 1112 and the third signal line 1121 have a third overlapping area 14, the first signal line 1111 and the fourth signal line 1122 are insulated in the second overlapping area 13, and/or, the second signal line 1112 and the third signal line 1121 are insulated in the third overlapping area 14, and the orthographic projections of the second overlapping area 13 and the third overlapping area 14 on the substrate 110 are at least partially located within orthographic projections of pixel openings 16 on the substrate 110, so that there is no need to arrange a via at a position of the second overlapping area 13 and/or the third overlapping area 14, and the number of vias can be reduced to reduce the impact on the display yield of the light-emitting unit 36 corresponding to the pixel opening 16.

The above-mentioned display panel 1 provided in the present application realizes that the third signal line 1121 and the fourth signal line 1122 transmit the same signal, and the first signal line 1111 and the third signal line 1121 are electrically connected, and the second signal line 1112 and the fourth signal line 1122 are electrically connected, so that the orthographic projections of the vias required for electrical connection on the substrate 110 are mostly or entirely located outside the orthographic projection of the pixel opening 16 on the substrate 110, thereby improving the problem of large color shift caused by the presence of the vias affecting the electrode flatness of the light-emitting unit 36 in the pixel opening 16, and improving the display quality of the display panel 1.

Specifically, a material of a first semiconductor layer 23 includes polysilicon semiconductor, and a material of a second semiconductor layer 26 includes metal oxide semiconductor.

In the above-mentioned embodiments, the second type transistor is an oxide semiconductor transistor, and the second type transistor may be a dual-gate transistor.

In the above-mentioned embodiments, a first insulating layer 30 is formed between the first semiconductor layer 23 and the first metal layer 24, a second insulating layer 31 is formed between the first metal layer 24 and the second metal layer 25, a third insulating layer 32 is formed between the second metal layer 25 and the second semiconductor layer 26, a fourth insulating layer 33 is formed between the second semiconductor layer 26 and the third metal layer 27, a fifth insulating layer 34 is formed between the third metal layer 27 and the fourth metal layer 28, a sixth insulating layer 35 is formed between the fourth metal layer 28 and the fifth metal layer 29, and the third signal line 1121 and the fourth signal line 1122 are formed in the fifth metal layer 29.

In a feasible embodiment, the first signal line 1111 and the second signal line 1112 are formed in the first metal layer 24, the first signal line 1111 and the third signal line 1121 are electrically connected through a first via in the first overlapping area 12, the second signal line 1112 and the fourth signal line 1122 are electrically connected through a second via in the fourth overlapping area 15, and the first via and the second via penetrate through the second insulating layer 31, the third insulating layer 32, the fourth insulating layer 33, the fifth insulating layer 34 and the sixth insulating layer 35.

In another feasible embodiment, the first signal line 1111 and the second signal line 1112 are formed in the second metal layer 25, the first signal line 1111 and the third signal line 1121 are electrically connected through a first via in the first overlapping area 12, the second signal line 1112 and the fourth signal line 1122 are electrically connected through a second via in the fourth overlapping area 15, and the first via and the second via penetrates through the third insulating layer 32, the fourth insulating layer 33, the fifth insulating layer 34 and the sixth insulating layer 35.

In another feasible embodiment, the first signal line 1111 and the second signal line 1112 are formed in the fourth metal layer 28, the first signal line 1111 and the third signal line 1121 are electrically connected through a first via in the first overlapping area 12, the second signal line 1112 and the fourth signal line 1122 are electrically connected through a second via in the fourth overlapping area 15, and the first via and the second via penetrate through the sixth insulating layer 35.

In another feasible embodiment, the first signal line 1111 and the second signal line 1112 are formed in the third metal layer 27, the first signal line 1111 and the third signal line 1121 are electrically connected through a first via in the first overlapping area 12, and the second signal line 1112 and the fourth signal line 1122 are electrically connected through a second via in the fourth overlapping area 15, and the first via and the second via penetrate through the fifth insulating layer 34 and the sixth insulating layer 35.

In a feasible embodiment, as shown in FIG. 16, the display panel also includes an isolation structure 37 and a light-emitting layer located on one side of the array base plate 11. The light-emitting layer includes a light-emitting unit 36. The isolation structure 37 includes a main body portion and an isolation opening 370 provided in the main body portion. The orthographic projection of the light-emitting unit 36 on the array base plate 11 is located within the orthographic projection of the isolation opening 370 on the array base plate 11.

Specifically, the light-emitting unit 36 includes a first electrode 361, a light-emitting functional layer 361, and a second electrode 363 stacked in a direction away from the substrate.

In the above-mentioned embodiments, the isolation structure 37 may be used to isolate the second electrode 363 and the light-emitting functional layer 362 of the light-emitting unit 36, so as to achieve the independence of different light-emitting units 36 from each other to improve the crosstalk problem between adjacent light-emitting units 36, which is conducive to improving the display quality of the display panel 1. At the same time, the use of the isolation structure 37 eliminates the need for a mask plate during the preparation of the light-emitting unit 36, which can reduce the spacing between the light-emitting units 36, thereby increasing the aperture ratio, and save costs.

Specifically, the isolation structure 37 includes a first isolation portion 371 and a second isolation portion 372 which are located on a side of the first isolation portion 371 away from the substrate 110, and an orthographic projection of the second isolation portion 372 on the substrate 110 covers an orthographic projection of the first isolation portion 371 on the substrate 110.

In the above-mentioned embodiments, a step portion may be formed between the second isolation portion 372 and the first isolation portion 371 in the isolation structure 37, and the light-emitting functional layer 362 and the second electrode 363 may be separated at the step portion to achieve mutual independence between different light-emitting units 36. Further optionally, the second electrode 362 is electrically connected to the first isolation portion 371, which is conducive to achieving the transmission needs of the power supply signal required inside the second electrode 362.

Patent PCT/CN2023/134518, US202310759370.2, US202310740412.8, US202310707209.0 and US202311346196.5 record the relevant technical solutions of the isolation structure, and the contents are incorporated into the present application by reference for reference.

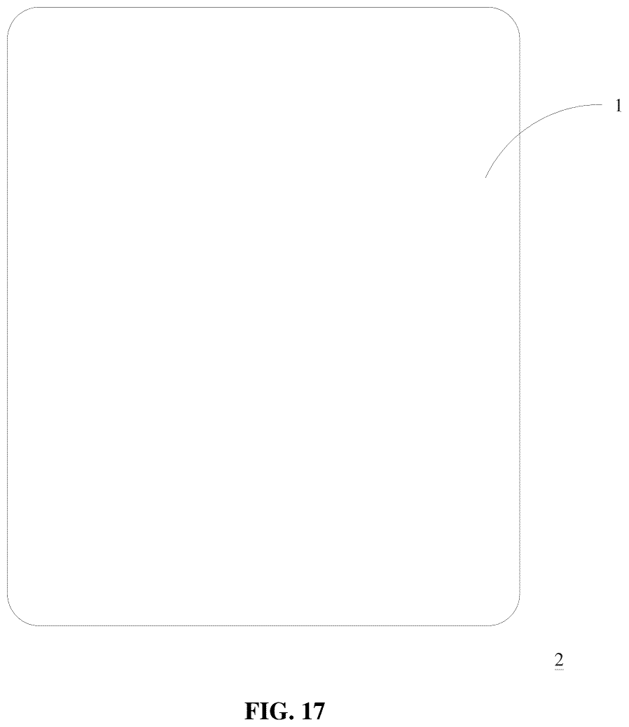

The present application also provides a display device 2, as shown in FIG. 17, including any one of the display panels 1 provided in the above-mentioned embodiments of the present application.

The color shift problem of the display device 2 is improved, and the display quality is improved, which is conducive to further improving the user experience.

The display device 2 may be a mobile terminal such as a mobile phone, a laptop computer, or a fixed terminal such as a TV, a computer monitor, or a wearable device such as a watch, etc., which is not specifically limited in the present application.

According to the embodiments of the present application as described above, these embodiments do not describe all the details in detail, nor do they limit the application to only specific embodiments. Apparently, according to the above description, many modifications and changes can be made. The present specification selects and specifically describes these embodiments in order to better explain the principles and practical applications of the present application, so that those skilled in the art can make good use of the present application and the modifications based on the present application. The present application is limited only by the claims and their full scope and equivalents.

What is claimed is:

1. A display panel, comprising:
an array base plate comprising a substrate and a first conductive layer, an insulating layer and a second conductive layer stacked in sequence on a side of the substrate, wherein
the first conductive layer comprises at least one first signal line and at least one second signal line each extending along a first direction, the second conductive layer comprises at least one third signal line and at least one fourth signal line each extending along a second direction, the first direction intersects with the second direction, the at least one first signal line and the at least one second signal line are arranged along the second direction, the at least one third signal line and the at least one fourth signal line are arranged along the first direction and transmit a same signal; and
in a direction perpendicular to the substrate, each of the at least one first signal line and each of the at least one third signal line have a first overlapping area, each of the at least one first signal line and each of the at least one fourth signal line have a second overlapping area, each of the at least one second signal line and each of the at least one third signal line have a third overlapping area, and each of the at least one second signal line and each of the at least one fourth signal line have a fourth overlapping area; the at least one first signal line and the at least one third signal line are electrically connected in the first overlapping area, the at least one first signal line and the at least one fourth signal line are insulated in the second overlapping area or the at least one second signal line and the at least one third signal line are insulated in the third overlapping area, and the at least one second signal line and the at least one fourth signal line are electrically connected in the fourth overlapping area; orthographic projections of the first overlapping area and the fourth overlapping area on the substrate are located outside orthographic projections of pixel openings on the substrate, and orthographic projections of the second overlapping area and the third overlapping area on the substrate are at least partially located within orthographic projections of pixel openings on the substrate, the pixel openings being located on a side of the array base plate in a direction from the substrate to the insulating layer.

2. The display panel according to claim 1, wherein the pixel openings comprise at least one first pixel opening, and the orthographic projections of the second overlapping area and the third overlapping area on the substrate are at least partially located within an orthographic projection of the at least one first pixel opening on the substrate;
the orthographic projections of the first overlapping area and the fourth overlapping area on the substrate are located outside the orthographic projection of the at least one first pixel opening on the substrate, and the at least one first pixel opening is configured to accommodate a blue light-emitting unit.

3. The display panel according to claim 2, wherein the pixel openings further comprise at least one second pixel opening, the at least one first pixel opening and the at least one second pixel opening are alternately arranged along the second direction and along the first direction, and the first overlapping area and the fourth overlapping area each are located between adjacent two of the at least one first pixel opening and the at least one second pixel opening along the second direction;
the at least one second pixel opening is configured to accommodate a red light-emitting unit.

4. The display panel according to claim 3, wherein the at least one first pixel opening comprises a plurality of first pixel openings, and the at least one second pixel opening comprises a plurality of second pixel openings, the first pixel openings and the second pixel openings are alternately arranged along the second direction to form first pixel columns, and in adjacent two of the first pixel columns, the first overlapping area and the third overlapping area are located in one of the first pixel columns, and the second overlapping area and the fourth overlapping area are located in the other of the first pixel columns.

5. The display panel according to claim 4, wherein the pixel openings further comprise at least one third pixel opening, the at least one third pixel opening comprises a plurality of third pixel openings, the third pixel openings are arranged along the second direction to form second pixel columns, and the first pixel columns and the second pixel columns are alternately arranged along the first direction.

6. The display panel according to claim 5, wherein two of the first pixel openings and two of the second pixel openings are arranged and alternately distributed around the at least one third pixel opening.

7. The display panel according to claim 5, wherein an orthographic projection of the first signal line on the substrate does not overlap an orthographic projection of the at least one second pixel opening or the at least one third pixel opening on the substrate and passes through the orthographic projection of the at least one first pixel opening on the substrate along the first direction;
an orthographic projection of the second signal line on the substrate does not overlap the orthographic projection of the at least one second pixel opening or the at least one third pixel opening on the substrate and passes through the orthographic projection of the at least one first pixel opening on the substrate along the first direction;
an orthographic projection of the third signal line on the substrate does not overlap the orthographic projection of the at least one third pixel opening on the substrate and passes through the orthographic projection of the at least one first pixel opening on the substrate and the orthographic projection of the at least one second pixel opening on the substrate along the second direction;
an orthographic projection of the fourth signal line on the substrate does not overlap the orthographic projection of the at least one third pixel opening on the substrate and passes through the orthographic projection of the at least one first pixel opening on the substrate and the orthographic projection of the at least one second pixel opening on the substrate along the second direction.

8. The display panel according to claim 1, wherein the at least one first signal line and the at least one fourth signal line are insulated in the second overlapping area, and the at least one second signal line and the at least one third signal line are insulated in the third overlapping area;
or, the at least one first signal line and the at least one fourth signal line are insulated in the second overlapping area, and the at least one second signal line and the at least one third signal line are electrically connected in the third overlapping area;
or, the at least one first signal line and the at least one fourth signal line are electrically connected in the second overlapping area, and the at least one second signal line and the at least one third signal line are insulated in the third overlapping area;
or, the at least one first signal line and the at least one fourth signal line are insulated in some of the second overlapping areas and electrically connected in some preset ones of the second overlapping areas, and the at least one second signal line and the at least one third signal line are insulated in some of the third overlapping areas and electrically connected in some preset ones of the third overlapping areas;
a sum of numbers of the preset ones of the second overlapping areas and the preset ones of the third overlapping areas is a half or one quarter of a sum of numbers of the second overlapping areas and the third overlapping areas.

9. The display panel according to claim 1, wherein the first conductive layer further comprises at least one fifth signal line and at least one sixth signal line each extending along the first direction, the second conductive layer further comprises at least one seventh signal line and at least one eighth signal line each extending along the second direction, the at least one fifth signal line and the at least one sixth signal line are arranged along the second direction, and the at least one seventh signal line and the at least one eighth signal line are arranged along the first direction and transmit a same signal.

10. The display panel according to claim 9, wherein the at least one third signal line and the at least one fourth signal line are arranged adjacently one anther along the first direction, the at least one seventh signal line and the at least one eighth signal line are arranged adjacently one another along the first direction; each of the at least one fifth signal line is located between one of the first signal lines and one of the second signal lines which ones are adjacent to each other, each of the at least one sixth signal line is located between one of the first signal lines and one of the second signal lines which ones are adjacent to each other, and one of the first signal lines or one of the second signal lines is arranged between each of the at least one fifth signal line and each of the at least one sixth signal line which are adjacent one another.

11. The display panel according to claim 10, wherein the pixel openings comprise at least one first pixel opening, at least one second pixel opening and at least one third pixel opening, the at least one first pixel opening and the at least one second pixel opening are arranged alternately along the second direction and the first direction, the at least one first pixel opening comprises a plurality of first pixel openings and the at least one second pixel opening comprises a plurality of second pixel openings, the first pixel openings and the second pixel openings are arranged alternately along the second direction to form a first pixel column, the at least one third pixel opening comprises a plurality of third pixel openings, the third pixel openings are arranged along the second direction to form a second pixel column, the first pixel columns and the second pixel columns are arranged alternately along the first direction, an orthographic projection of the at least one fifth signal line on the substrate does not overlap an orthographic projection of the at least one first pixel opening or the at least one second pixel opening on the substrate, and an orthographic projection of the at least one first signal line on the substrate passes through an orthographic projection of the at least one third pixel opening on the substrate along the first direction;
the orthographic projections of the second overlapping area and the third overlapping area on the substrate are at least partially located within the orthographic projection of the at least one first pixel opening on the substrate;
the first overlapping area and the fourth overlapping area each are located between adjacent two of the first pixel openings and the second pixel openings along the second direction;
in adjacent two of the first pixel columns, the first overlapping area and the third overlapping area are located in one of the first pixel columns, and the second overlapping area and the fourth overlapping area are located in the other first pixel column;
an orthographic projection of the at least one sixth signal line on the substrate does not overlap the orthographic projection of the at least one first pixel opening or the at least one second pixel opening on the substrate and passes through the orthographic projection of the at least one third pixel opening on the substrate along the first direction;
an orthographic projection of the at least one seventh signal line on the substrate does not overlap the orthographic projection of the at least one third pixel opening on the substrate and passes through the orthographic projection of the at least one first pixel opening on the substrate and the orthographic projection of the at least one second pixel opening on the substrate along the second direction;
an orthographic projection of the at least one eighth signal line on the substrate does not overlap the orthographic projection of the at least one third pixel opening on the substrate and passes through the orthographic projection of the at least one first pixel opening on the substrate and the orthographic projection of the at least one second pixel opening on the substrate along the second direction.

12. The display panel according to claim 11, wherein the at least one first signal line further comprises a first extension portion connected to the second overlapping area and arranged with the second overlapping area along the second direction, an orthographic projection of the first extension portion on the substrate being at least partially located outside the orthographic projection of the at least one first pixel opening on the substrate, the first extension portion being electrically connected to the fourth signal line through a first through hole, and an orthographic projection of the first through hole on the substrate does not overlap the orthographic projection of the at least one first pixel opening on the substrate;
the at least one fifth signal line comprises a first partition area for accommodating the first extension portion at least partially located in the first partition area.

13. The display panel according to claim 11, wherein the at least one second signal line further comprises a second extension portion connected to the third overlapping area and arranged with the third overlapping area along the second direction, an orthographic projection of the second extension portion on the substrate being at least partially located outside the orthographic projection of the at least one first pixel opening on the substrate, the second extension portion being electrically connected to the at least one third signal line through a second through hole, and an orthographic projection of the second through hole on the substrate does not overlap the orthographic projection of the at least one first pixel opening on the substrate;
the at least one sixth signal line comprises a second partition area for accommodating the second extension portion at least partially located in the second partition area.

14. The display panel according to claim 9, wherein each of the at least one fifth signal line and each of the at least one seventh signal line have a fifth overlapping area, each of the at least one fifth signal line and each of the at least one eighth signal line have a sixth overlapping area, each of the at least one sixth signal line and each of the at least one seventh signal line have a seventh overlapping area, and each of the at least one sixth signal line and each of the at least one eighth signal line have an eighth overlapping area; the at least one fifth signal line and the at least one seventh signal line are electrically connected in the fifth overlapping area, the at least one sixth signal line and the at least one eighth signal line are electrically connected in the eighth overlapping area or the at least one fifth signal line and the at least one eighth signal line are electrically connected in the sixth overlapping area, and the at least one sixth signal line and the at least one seventh signal line are electrically connected in the seventh overlapping area.

15. The display panel according to claim 9, wherein the at least one third signal line has a first reset signal, and the at least one seventh signal line has a second reset signal;
the display panel further comprises a plurality of driving circuits, each of the driving circuits is electrically connected to at least one light-emitting unit and comprises a first light-emitting control module, a first initialization module, and a second initialization module;
a control end of the second initialization module is electrically connected to a first scanning signal line, a first end of the second initialization module is electrically connected to the second reset signal line, and a second end of the second initialization module is electrically connected to a first end of the first light-emitting control module;
a control end of the first initialization module is electrically connected to the first scanning signal line, a first end of the first initialization module is electrically connected to the first reset signal line, and a second end of the first initialization module is electrically connected to a second end of the first light-emitting control module and the light-emitting unit.

16. The display panel according to claim 1, wherein the display panel further comprises a first high-level signal line located in the second conductive layer and extending along the second direction, part of an orthographic projection of the first high-level signal line on the substrate located within the orthographic projections of the at least one second pixel opening and the at least one first pixel opening on the substrate is symmetrical with respect to a symmetry axis parallel to the second direction.

17. A display panel, comprising an array base plate including a substrate and a first semiconductor layer, a first metal layer, a second metal layer, a second semiconductor layer, a third metal layer, a fourth metal layer and a fifth metal layer stacked in a direction away from the substrate, wherein
the array base plate comprises a first type transistor, a second type transistor and a capacitor, the first semiconductor layer is configured to form a source region, a drain region and a channel region of the first type transistor, the first metal layer is configured to form a gate of the first type transistor and a first polar plate of the capacitor, the second metal layer is configured to form a bottom gate of the second type transistor, the second semiconductor layer is configured to form a source region, a drain region and a channel region of the second type transistor, the third metal layer is configured to form a top gate of the second type transistor, and the fourth metal layer is configured to form sources and drains of the first type transistor and the second type transistor;
wherein one of the first metal layer, the second metal layer, the third metal layer and the fourth metal layer is formed with at least one first signal line and at least one second signal line each extending along a first direction and arranged in the second direction, and the fourth metal layer is formed with at least one third signal line and at least one fourth signal line each extending along the second direction and arranged in the first direction, the first direction intersects with the second direction, and the at least one third signal line and the at least one fourth signal line transmit a same signal;
in a direction perpendicular to the substrate, each of the at least one first signal line and each of the at least one third signal line have a first overlapping area, each of the at least one first signal line and each of the at least one fourth signal line have a second overlapping area, each of the at least one second signal line and each of the at least one third signal line have a third overlapping area, and each of the at least one second signal line and each of the at least one fourth signal line have a fourth overlapping area; the at least one first signal line and the at least one third signal line are electrically connected in the first overlapping area, the at least one first signal line and the at least one fourth signal line are insulated in the second overlapping area or the at least one second signal line and the at least one third signal line are insulated in the third overlapping area, the at least one second signal line and the at least one fourth signal line are electrically connected in the fourth overlapping area; orthographic projections of the first overlapping area and the fourth overlapping area on the substrate are located outside orthographic projections of pixel openings on the substrate, and orthographic projections of the second overlapping area and the third overlapping area on the substrate are at least partially located within orthographic projections of pixel openings on the substrate.

18. The display panel according to claim 17, wherein a first insulating layer is formed between the first semiconductor layer and the first metal layer, a second insulating layer is formed between the first metal layer and the second metal layer, a third insulating layer is formed between the second metal layer and the second semiconductor layer, a fourth insulating layer is formed between the second semiconductor layer and the third metal layer, a fifth insulating layer is formed between the third metal layer and the fourth metal layer, a sixth insulating layer is formed between the fourth metal layer and the fifth metal layer, and the at least one third signal line and the at least one fourth signal line are formed in the fifth metal layer;
the at least one first signal line and the at least one second signal line are formed in the first metal layer, the first at least one signal line and the at least one third signal line are electrically connected through a first via in the first overlapping area, the at least one second signal line and the at least one fourth signal line are electrically connected through a second via in the fourth overlapping area, and the first via and the second via penetrate through the second insulating layer, the third insulating layer, the fourth insulating layer, the fifth insulating layer and the sixth insulating layer;
or, the at least one first signal line and the at least one second signal line are formed in the second metal layer, the at least one first signal line and the at least one third signal line are electrically connected through a first via in the first overlapping area, the at least one second signal line and the at least one fourth signal line are electrically connected through a second via in the fourth overlapping area, and the first via and the second via penetrates through the third insulating layer, the fourth insulating layer, the fifth insulating layer and the sixth insulating layer;
or, the at least one first signal line and the at least one second signal line are formed in the fourth metal layer, the at least one first signal line and the at least one third signal line are electrically connected through a first via in the first overlapping area, the at least one second signal line and the at least one fourth signal line are electrically connected through a second via in the fourth overlapping area, and the first via and the second via penetrate through the sixth insulating layer;
or, the at least one first signal line and the at least one second signal line are formed in the third metal layer, the at least one first signal line and the at least one third signal line are electrically connected through a first via in the first overlapping area, and the at least one second signal line and the at least one fourth signal line are electrically connected through a second via in the fourth overlapping area, and the first via and the second via penetrate through the fifth insulating layer and the sixth insulating layer;
a material of the first semiconductor layer comprises polysilicon semiconductor, and a material of the second semiconductor layer comprises metal oxide semiconductor.

19. The display panel according to claim 17, further comprising a light-emitting layer and an isolation structure which are located on a side of the array base plate, the light-emitting layer including a light-emitting unit, the isolation structure including a main body portion and an isolation opening arranged in the main body portion, and an orthographic projection of the light-emitting unit on the array base plate is located within an orthographic projection of the isolation opening on the array base plate;
the main body portion comprises a first isolation portion and a second isolation portion, the second isolation portion is located on a side of the first isolation portion away from the array base plate, and an orthographic projection of the second isolation portion on the array base plate covers an orthographic projection of the first isolation portion on the array base plate;
the light-emitting unit comprises a first electrode, a light-emitting functional layer, and a second electrode stacked in a direction away from the substrate, and the second electrode is electrically connected to the first isolation portion.

20. A display device, comprising a display panel according to claim 1.
